(19) United States
(12) Patent Application Publication
(10) Pub. No.: US 2023/0074925 A1
(43) Pub. Date: Mar. 9, 2023

(54) QUAMTUM DOT LIGHT EMITTING DIODE AND METHOD FOR MANUFACTURING THE SAME, DISPLAY PANEL, AND DISPLAY DEVICE

(71) Applicant: BOE Technology Group Co., Ltd., Beijing (CN)

(72) Inventor: Xiaoyuan ZHANG, Beijing (CN)

(21) Appl. No.: 17/798,162

(22) PCT Filed: Jun. 8, 2021
(86) PCT No.: PCT/CN2021/098936

§ 371 Date: Aug. 8, 2022

(30) Foreign Application Priority Data
Jun. 12, 2020 (CN) 202010535254.9

(51) Int. Cl. H01L 51/50; H01L 51/56

(52) U.S. Cl. CPC H01L 51/508; H01L 51/502; H01L 51/56; H01L 2251/5369; H01L 2251/558

(57) ABSTRACT

A quantum dot light emitting diode and a method for manufacturing the same are provided, a display panel, and a display device, belonging to the display technical field. The quantum dot light emitting diode comprises: a base substrate; a first electrode, a first electron transport layer, a second electron transport layer, a quantum dot light emitting layer, a hole transport layer, a hole injection layer and a second electrode successively located on the base substrate, where a surface roughness of a side of the first electron transport layer away from the first electrode is less than a threshold, and the second electron transport layer is composed of nanoparticles.

### CROSS REFERENCE TO RELATED APPLICATIONS

This application claims the priority to Chinese Patent Application No. 202010535254.9, filed in China on Jun. 12, 2020, which is incorporated herein by reference in its entirety.

### TECHNICAL FIELD

The present disclosure relates to display technical field, and in particular to a quantum dot light emitting diode and a method for manufacturing the same, a display panel, and a display device.

### BACKGROUND

Quantum dot is also called semiconductor nanocrystal, and it is composed of a small number of atoms with the size of 1 nm˜100 nm zero-dimensional nanostructure in three dimensions. Quantum dot has tunable band gap and narrow emission spectrum. In recent years, it is widely used in LED (light emitting diode) devices. Quantum dot light emitting diode has the advantages of self-light-emitting, high color purity, low energy consumption, image stability, wide angle of view range, rich color and so on. In recent years, it is considered as a new generation of display technology after LCD and OLED (organic light emitting diode), and has broad application prospects.

In recent years, with the continuous development of quantum dot electro-induced light-emitting technology, many achievements have been made in device efficiency and lifetime. In terms of the structure, a quantum dot light-emitting device can be divided into an upright structure and an inverted structure, where the upright structure generally uses a conductive ITO as a anode, and then sequentially deposits a hole injection layer, a hole transport layer, a quantum dot light emitting layer, an electron transport layer and a cathode; the inverted structure uses an ITO conductive glass as a cathode on which the electron transport layer is deposited directly followed by the quantum dot light emitting layer, the hole transport layer, the hole injection layer and a metal anode. For the quantum dot light-emitting device with the inverted structure, there is light-emitting inhomogeneity.

### SUMMARY

Technical solutions provided by the embodiments of the present disclosure are as follows.

In one aspect, a quantum dot light emitting diode is provided, comprising:

a base substrate; and

a first electrode, a first electron transport layer, a second electron transport layer, a quantum dot light emitting layer, a hole transport layer, a hole injection layer and a second electrode successively located on the base substrate, where a surface roughness of a side of the first electron transport layer away from the first electrode is less than a threshold, and the second electron transport layer is composed of nanoparticles.

In some embodiments, the first electron transport layer is a film layer formed from one of the following materials: zinc oxide, aluminum zinc oxide and magnesium zinc oxide.

In some embodiments, the second electron transport layer is composed of nanoparticles of one of the following materials: zinc oxide, aluminum zinc oxide and magnesium zinc oxide.

In some embodiments, the surface roughness has the threshold of 3 nm.

In some embodiments, the first electron transport layer has the thicknesses of 50-150 nm and the second electron transport layer has the thicknesses of 20-60 nm.

In some embodiments, the first electrode is an ITO cathode.

In some embodiments, the second electrode is a metal anode.

The embodiments of the present disclosure also provide a display panel, comprising the quantum dot light emitting diode as described above.

The embodiments of the present disclosure also provide a display device, comprising the quantum dot light emitting diode as described above.

The embodiments of the present disclosure also provide a method for manufacturing the quantum dot light emitting diode, comprising:

providing a base substrate; and

successively forming the first electrode, the first electron transport layer, the second electron transport layer, the quantum dot light emitting layer, the hole transport layer, the hole injection layer and the second electrode on the base substrate, where the surface roughness of a side of the first electron transport layer away from the first electrode is less than the threshold, and the second electron transport layer is composed of nanoparticles.

In some embodiments, the first electron transport layer is fabricated on the first electrode by using a sol-gel method, a sputtering film-forming process, or a vapor deposition method.

In some embodiments, the second electron transport layer is fabricated by using a spin coating film-forming process with nanoparticle solution.

In some embodiments, the first electron transport layer and the second electron transport layer are formed from one of the following materials: zinc oxide, aluminum zinc oxide and magnesium zinc oxide. In some embodiments, the concentration of the sol for fabricating the first electron transport layer is 50 mg/ml-150 mg/ml.

In some embodiments, a carrier mobility of the first electron transport layer is adjusted by an annealing temperature within the range of 120° C.-350° C.

In some embodiments, the first electron transport layer is formed by annealing at a temperature of 320° C. for 30 minutes.

In some embodiments, the concentration of the nanoparticle solution for fabricating the second electron transport layer is 10 mg/ml-50 mg/ml.

In some embodiments, the second electron transport layer with the thicknesses of 45 nm is formed by nanoparticle solution of concentration of 30 mg/ml.

### BRIEF DESCRIPTION OF THE DRAWINGS

FIG. 1 is a structural diagram of a quantum dot light emitting diode of the embodiments of the present disclosure;

FIG. 2 is a schematic illustration of forming a first electron transport layer of the embodiments of the present disclosure;

FIG. 3 is a diagram showing a comparison between a related art display device and a display device fabricated by the embodiments of the present disclosure;

FIG. 4 is a schematic illustration of a surface topography test of a ZnO nanoparticle film by using a spin coating film-forming process;

FIG. 5 is a schematic illustration showing the surface topography test of a ZnO thin film fabricated by using a sol-gel method.

### REFERENCE NUMERALS

1 base substrate

2 first electrode

3 first electron transport layer

31 Zno sol

4 second electron transport layer

5 quantum dot light emitting layer

6 hole transport layer

7 hole injection layer

8 second electrode

### DETAILED DESCRIPTION

In order that the technical problems, technical solutions, and advantages to be solved by the embodiments of the present disclosure may become more apparent, a more detailed description of the disclosure will be rendered by reference to the drawings and the specific embodiments.

In recent years, with the continuous development of quantum dot electro-induced light-emitting technology, many achievements have been made in device efficiency and lifetime. In terms of the structure, a quantum dot light-emitting device can be divided into an upright structure and an inverted structure, where the upright structure generally uses a conductive ITO as a anode, and then sequentially deposits a hole injection layer, a hole transport layer, a quantum dot light emitting layer, an electron transport layer and a cathode; the inverted structure uses an ITO conductive glass as a cathode on which the electron transport layer is deposited directly followed by the quantum dot light emitting layer, the hole transport layer, the hole injection layer and a metal anode. An organic hole-injecting material and hole-transporting material are often used in the quantum dot light-emitting device with the upright structure. An energy level of the organic material can be easily adjusted by changing the structure of material, which can better match with electrode for energy level and improve the hole-injecting ability. However, the use of organic hole-injecting material and hole-transporting material for the quantum dot light-emitting device with the upright structure has a big problem, namely, it is difficult to realize patterning during the process of patterning of a light-emitting pixel unit, while the quantum dot light-emitting device with the inverted structure usually deposits an inorganic material on an ITO cathode, such as an inorganic ZnO nanoparticle for the electron transport layer, and this structure is easier to achieve the patterning of the pixel unit, so there is a structural advantage to a certain extent.

However, on the other hand, since the surface of an ITO electrode is uneven, the quantum dot light-emitting device with the upright structure can usually be performed on interface modification with the organic material to reduce the surface roughness of the electrode so as to improve the film-forming performance, while the quantum dot light-emitting device with the inverted structure has poor film-forming performance and non-uniform film layer topography due to the larger particles of ZnO nanoparticles during the fabrication, so the fabricated quantum dot light-emitting device tends to have non-uniform light-emitting.

The embodiments of the present disclosure provide a quantum dot light emitting diode and a method for manufacturing the same, display panel, display device, which can improve the uniformity of display device light-emitting.

The embodiments of the present disclosure provide a quantum dot light emitting diode, as shown in FIG. 1, comprising:

a base substrate 1; and

a first electrode 2, a first electron transport layer 3, a second electron transport layer 4, the quantum dot light emitting layer 5, the hole transport layer 6, the hole injection layer 7 and a second electrode 8 successively located on the base substrate 1, where the surface roughness of a side of the first electron transport layer away from the first electrode is less than a threshold, and the second electron transport layer is composed of nanoparticles.

In this embodiment, the first electron transport layer is formed on the first electrode before the second electron transport layer is formed by using the nanoparticles, and a surface roughness of the first electron transport layer is relatively small. After the first electron transport layer is formed on the first electrode, the first electron transport layer can improve an interface between the first electrode and the second electron transport layer, improve the uneven surface of the first electrode, and provide a relatively flat surface for forming the second electron transport layer, avoiding the problem of forming the nanoparticles directly on the uneven first electrode resulting in a poor topography of the second electron transport layer, so that the second electron transport layer composed of the nanoparticles has a better film-forming property and a good topography; thereby the light-emitting homogeneity of the quantum dot light emitting diode can be improved.

Where the base substrate 1 generally uses a glass substrate, and in the inverted structure, the first electrode can be cathode, and the second electrode can be anode; alternatively, if the upright structure is used, the first electrode may be anode and the second electrode may be cathode.

Specifically, an integral layer's ITO can be made on the glass substrate as the first electrode, and the surface of the side of the first electrode 2 away from the base substrate 1 is uneven due to the limitations of fabrication process and materials. The second electrode 8 can be made of a well-conducting metal such as silver.

The material of the first electron transport layer 3 and the second electron transport layer 4 may be selected from: zinc oxide, aluminum zinc oxide and magnesium zinc oxide, the material of the first electron transport layer 3 and the second electron transport layer 4 may be the same or different, and the second electron transport layer 4 is composed of nanoparticles.

The first electron transport layer 3 can be fabricated by a sol-gel method, a sputtering film-forming process or a vapor deposition method, and the first electron transport layer 3 fabricated in the above-mentioned manner has a good density and a smooth surface without holes or unevenness on the surface. Since the sol-gel method can relatively easily control the thicknesses and uniformity of film formation by changing the concentration of the precursor solution, forming the first electron transport layer 3 by using the sol-gel method can not only improve the interface between the first electrode and the second electron transport layer but also control an electron transfer rate by adjusting the film layer thicknesses. In some embodiments, the surface roughness of the first electron transport layer 3 is less than 3 nm, that is, the difference value of maximum value and minimum value of the surface level of the first electron transport layer 3 is not more than 3 nm.

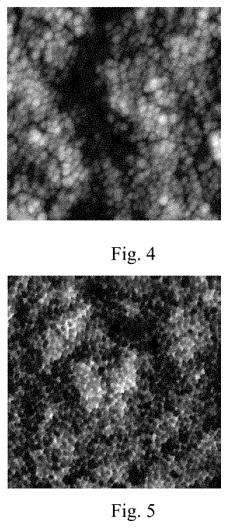

The second electron transport layer 4 may be fabricated by the spin coating film-forming process. In a specific embodiment, the first electron transport layer 3 and the second electron transport layer 4 can both use zinc oxide ZnO; if the ZnO nanoparticles are directly deposited on the first electrode 2 by the spin coating film-forming process to fabricate the second electron transport layer 4, the surface topography test is performed by an atomic force microscope, as shown in FIG. 4, it can be seen that the surface of the second electron transport layer 4 is uneven, and the surface roughness is 4.84 nm; if the ZnO thin film is fabricated on the first electrode 2 as the first electron transport layer 3, and the surface topography test is performed by the atomic force microscope, as shown in FIG. 5, it can be seen that the surface of the first electron transport layer 3 has a relatively compact ZnO arrangement and a flat surface, and the surface roughness is 2.82 nm; therefore, the first electron transport layer 3 with the low surface roughness can be fabricated by using the sol-gel method, and the second electron transport layer 4 is fabricated on the surface of the first electron transport layer 3, thus the surface roughness of the second electron transport layer 4 can be improved.

In some embodiments, the thicknesses of the first electron transport layer can be 50-150 nm, and the thicknesses of the second electron transport layer can be 20-60 nm; and when the above-mentioned value range is adopted, the carrier mobility of the first electron transport layer 3 and the second electron transport layer 4 are better.

According to the solution of the embodiments of the present disclosure, the first electron transport layer is formed on the first electrode before the second electron transport layer is formed by using the nanoparticles, and the surface roughness of the first electron transport layer is relatively small. After the first electron transport layer is formed on the first electrode, the first electron transport layer can improve the interface between the first electrode and the second electron transport layer, improve the uneven surface of the first electrode, and provide the relatively flat surface for forming the second electron transport layer, avoiding the problem of forming the nanoparticles directly on the uneven first electrode resulting in the poor topography of the second electron transport layer, so that the second electron transport layer composed of the nanoparticles has the better film-forming property and the good topography; thereby the light-emitting homogeneity of the quantum dot light emitting diode can be improved.

The embodiments of the present disclosure also provide a display panel, comprising the quantum dot light emitting diode as described above.

The embodiments of the present disclosure also provide a display device, comprising the quantum dot light emitting diode as described above. The display device includes, but is not limited to: components such as a radio frequency cell, a network module, an audio export cell, an import cell, a sensor, a display cell, a user input unit, an interface unit, a memory, a processor, a power and the like. It will be appreciated by those skilled in the art that the structure of the display device described above is not intended to be limitation of the display device, and that the display device may include more or fewer of the components described above, or some components may be combined, or a different arrangement of the components. In the embodiments of the present disclosure, the display device includes, but is not limited to, a monitor, a cell phone, a tablet computer, a television, a wearable electronic device, a navigation display device, etc.

The display device can be: any product or component with display function such as the television, the monitor, a digital photo frame, the cell phone and the tablet computer, where the display device further comprises a flexible circuit board, a printed circuit board and a backplate.

The embodiments of the present disclosure also provide a method for manufacturing the quantum dot light emitting diode, as shown in FIG. 1, comprising:

providing the base substrate 1; and

successively forming the first electrode 2, the first electron transport layer 3, the second electron transport layer 4, the quantum dot light emitting layer 5, the hole transport layer 6, the hole injection layer 7 and the second electrode 8 on the base substrate 1, where the surface roughness of a side of the first electron transport layer away from the first electrode is less than the threshold, and the second electron transport layer is composed of nanoparticles.

In this embodiment, the first electron transport layer is formed on the first electrode before the second electron transport layer is formed by using the nanoparticles, and the surface roughness of the first electron transport layer is relatively small. After the first electron transport layer is formed on the first electrode, the first electron transport layer can improve the interface between the first electrode and the second electron transport layer, improve the uneven surface of the first electrode, and provide the relatively flat surface for forming the second electron transport layer, avoiding the problem of forming the nanoparticles directly on the uneven first electrode resulting in the poor topography of the second electron transport layer, so that the second electron transport layer composed of the nanoparticles has the better film-forming property and the good topography; thereby the light-emitting homogeneity of the quantum dot light emitting diode can be improved.

Where the base substrate 1 generally uses the glass substrate, the first electrode can be cathode, and the second electrode can be anode; alternatively, the first electrode may be anode and the second electrode may be cathode.

Specifically, the integral layer's ITO can be made on the glass substrate as the first electrode, and the surface of the side of the first electrode 2 away from the base substrate 1 is uneven due to the limitations of fabrication process and materials. The second electrode 8 can be made of the well-conducting metal such as silver.

The material of the first electron transport layer 3 and the second electron transport layer 4 may be selected from: zinc oxide, aluminum zinc oxide and magnesium zinc oxide, the material of the first electron transport layer 3 and the second electron transport layer 4 may be the same or different.

In some embodiments, the first electron transport layer is fabricated by the sol-gel method, the sputtering film-forming process or the vapor deposition method, and the first electron transport layer 3 fabricated in the above-mentioned manner has the good density and the smooth surface, without holes or unevenness on the surface. Since the sol-gel method can relatively easily control the thicknesses and uniformity of film formation by changing the concentration of the precursor solution, the first electron transport layer 3 can be formed by using the sol-gel method, which can not only improve the interface between the first electrode and the second electron transport layer but also control the electron transfer rate by adjusting the film layer thicknesses. In some embodiments, the surface roughness of the first electron transport layer 3 is less than 3 nm, that is, the difference value of maximum value and minimum value of the surface level of the first electron transport layer 3 is not more than 3 nm.

In some embodiments, the second electron transport layer can be fabricated by using the spin coating film-forming process with nanoparticle solution.

In a specific embodiment, a method for manufacturing the quantum dot light emitting diode comprises the following steps.

In step 1, a layer of ITO on the glass substrate is fabricated as cathode, the formed ITO glass substrate is washed successively by water and ethanol for twice, and is treated with ultraviolet ozone for ten minutes after drying.

In step 2, the ZnO sol needed to make the first electron transport layer 3 is prepared.

The 96% methoxyethanol and 4% ethanolamine are used as solvents to prepare zinc acetate solution with concentration of 75 mg/ml, where ethanolamine is used as a stabilizer, the solution is stirred and mixed evenly, so that the solid is fully dissolved. The solution is spin-coated on the ITO glass substrate, followed by annealing at a temperature of 300° C. for 5 minutes to obtain the ZnO film, then the ZnO surface is washed with deionized water, ethanol and acetone respectively, followed by annealing at a temperature of 200° C. for 5 minutes to remove excess solvent, and finally the ZnO film with the smoother surface as the first electron transport layer 3 is obtained.

The ZnO film layer fabricated by the sol-gel method can adjust the thicknesses thereof by adjusting the concentration of solution, the concentration can be 50 mg/ml-150 mg/ml, and the thicknesses can be 50 nm-150 nm; the carrier mobility of ZnO film layer can be adjusted by the annealing temperature, where the annealing temperature can be 120° C. to 350° C.

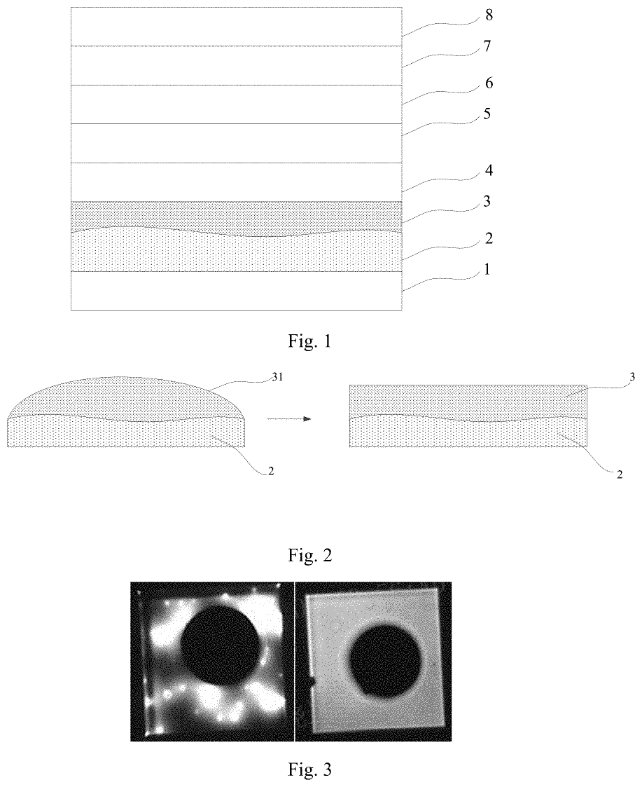

In a specific embodiment, as shown in FIG. 2, after forming a ZnO sol 31 on the first electrode 2, the planar first electron transport layer 3 can be obtained by annealing at a temperature of 320° C. for 30 minutes.

The surface topography of the ZnO film layer formed in the above manner is tested by the atomic force microscope, and it can be observed the surface of the first electron transport layer 3 has the relatively compact ZnO arrangement and the flat surface with the roughness of 2.82 nm.

In step 3, the solution of ZnO nanoparticles with the concentration of 30 mg/ml is spin-coated on the above ZnO film layer, the ethanol is used for washing followed by annealing at a temperature of 120° C. for 10 minutes to obtain the second electron transport layer 4 with flatter film layer.

The thicknesses of the layer of ZnO film can be adjusted by the solution concentration of the ZnO nanoparticles, and the film layer thicknesses can be adjusted by adjusting the solution concentration of the nanoparticles according to the difference between device structure and the functional material used, where the solution concentration of the nanoparticles can be 10 mg/ml to 50 mg/ml and the thicknesses of the second electron transport layer 4 can be 20 nm to 60 nm.

At the solution concentration of 30 mg/ml of ZnO nanoparticles, the thickness of the formed ZnO film is about 45 nm.

Where when zinc acetate sol with the concentration of 75 mg/ml is used and the 150° C. annealing temperature is used, the thicknesses of the fabricated first electron transport layer 3 is about 75-85 nm; when the solution concentration of the ZnO nanoparticles is 30 mg/ml, the fabricated second electron transport layer 4 thicknesses is about 45-55 nm, and when the thicknesses of the first electron transport layer 3 and the second electron transport layer 4 adopt the above value, the efficiency of the fabricated green light-emitting device reaches 27 cd/A.

In step 4, the quantum dot solution with the concentration of 15 mg/ml is spin-coated on the second electron transport layer 4 and is annealed at a temperature of 120° C. for 5 minutes to obtain the quantum dot light emitting layer.

The thicknesses of quantum dot light emitting layer can be adjusted according to the concentration of the quantum dot solution, and the concentration of the quantum dot solution can be 5 mg/ml-30 mg/ml, where when the concentration of the quantum dot solution is 15 mg/ml, the thicknesses of the fabricated quantum dot light emitting layer is about 30 nm. The quantum dot light emitting layer may include a plurality of quantum dot light emitting layers of different colors, such as a red quantum dot light emitting layer, a green quantum dot light emitting layer, and a blue quantum dot light emitting layer.

In step 5, the hole transport layer with the thicknesses of 40 nm and the hole injection layer with the thicknesses of 5 nm are successively deposited on the quantum dot light emitting layer by means of vacuum plating.

Where the thicknesses of hole transport layer and hole injection layer can be adjusted by evaporation rate and time.

In step 6, silver with the thicknesses of 120 nm is deposited as the second electrode by means of vacuum plating.

Where the second electrode can be cathode, and the thicknesses can be 80 nm-200 nm.

When the quantum dot light emitting diode fabricated by the above-mentioned steps is applied to the display device, the light-emitting of the display device is uniform; however, for quantum dot light emitting diode using only ZnO nanoparticles as electron transport layer, when applied to display device, the light-emitting of display device is not uniform, with obvious bright and dark spots.

FIG. 3 is a microscope photograph when the display device is illuminated, and the left half in the figure is divided into a green light-emitting device applied by quantum dot light emitting diode which only uses ZnO nanoparticles as the electron transport layer. It can be seen that when the device is illuminated at 5 V voltage, the light-emitting topography of the pixel region shows obvious unevenness; the right half in the figure is the light-emitting topography of the pixel region when the fabricated display device of the present embodiment is illuminated at 5 V voltage, and the light-emitting topography is uniform everywhere and the topography is good.

In each method embodiment of the present disclosure, the sequence number of each step cannot be used to define the sequence of each step, and for the ordinary skilled in the art, without involving any inventive effort, the sequence of each step is also within the protected range of the present disclosure.

It should be noted that each embodiment in this specification is described in a progressive manner, the same and similar parts between each embodiment can be referred to each other, and each embodiment focuses on the differences from other embodiments. In particular, for the embodiments, since they are substantially similar to the product embodiments, the description is relatively simple, and it is sufficient to refer to the partial description of the product embodiments.

Unless defined otherwise, technical or scientific terms used in this disclosure shall have the ordinary meaning as understood by the ordinary skilled in the art to which this disclosure belongs. The words “first”, “second”, and the like used in this disclosure do not denote any order, quantity, or importance, but rather are used to distinguish one element from another. The words “comprise” or “include”, and the like, mean that the presence of an element or item preceding the word covers the presence of the element or item listed after the word and equivalents thereof, but do not exclude other elements or items. The words “connecting” or “connected” and the like are not limited to physical or mechanical connections, but may include electrical connections, whether direct or indirect. The terms “upper”, “lower”, “left”, “right”, etc. are used only to indicate a relative position relationship, which may change accordingly when the absolute position of the object described changes.

It will be understood that when the element such as a layer, a film, a region, or a substrate is referred to “on” or “under” another element, it can be “directly” “on” or “under” another element or intervening element may be present.

In the above description of the embodiments, particular features, structures, materials or characteristics may be combined in any suitable manner in any one or more of the embodiments or examples.

The above-mentioned is only the specific embodiments of the present disclosure, but the protection range of the present disclosure is not limited thereto, and any person skilled in the art who is familiar with the present technical field would have readily conceived of changes or substitutions within the technical range disclosed in the present disclosure, and all would be covered by the protection range of the present disclosure. Accordingly, the protection range of this disclosure shall control over the protection range of the claims.

1. A quantum dot light emitting diode, comprising:
a base substrate; and
a first electrode, a first electron transport layer, a second electron transport layer, a quantum dot light emitting layer, a hole transport layer, a hole injection layer and a second electrode successively located on the base substrate, wherein a surface roughness of a side of the first electron transport layer away from the first electrode is less than a threshold, and the second electron transport layer is composed of nanoparticles.

2. The quantum dot light emitting diode according to claim 1, wherein the first electron transport layer is a film layer formed from one of the following materials: zinc oxide, aluminum zinc oxide and magnesium zinc oxide.

3. The quantum dot light emitting diode according to claim 1, wherein the second electron transport layer is composed of nanoparticles of one of the following materials: zinc oxide, aluminum zinc oxide and magnesium zinc oxide.

4. The quantum dot light emitting diode according to claim 1, wherein the surface roughness has a threshold of 3 nm.

5. The quantum dot light emitting diode according to claim 1, wherein the first electron transport layer has a thickness of 50-150 nm and the second electron transport layer has a thickness of 20-60 nm.

6. The quantum dot light emitting diode according to claim 1, wherein the first electrode is an ITO cathode.

7. The quantum dot light emitting diode according to claim 5, wherein the second electrode is a metal anode.

8. A display panel, comprising the quantum dot light emitting diode according to claim 1.

9. A display device, comprising the quantum dot light emitting diode according to claim 1.

10. A method for manufacturing a quantum dot light emitting diode, comprising:
providing a base substrate; and
successively forming a first electrode, a first electron transport layer, a second electron transport layer, a quantum dot light emitting layer, a hole transport layer, a hole injection layer and a second electrode on the base substrate, wherein a surface roughness of a side of the first electron transport layer away from the first electrode is less than a threshold, and the second electron transport layer is composed of nanoparticles.

11. The manufacturing method according to claim 10, wherein the first electron transport layer is fabricated on the first electrode by using a sol-gel method, a sputtering film-forming process, or a vapor deposition method.

12. The manufacturing method according to claim 10, wherein the second electron transport layer is fabricated by using a spin coating film-forming process with nanoparticle solution.

13. The manufacturing method according to claim 10, wherein the first electron transport layer and the second electron transport layer are formed from one of the following materials: zinc oxide, aluminum zinc oxide and magnesium zinc oxide.

14. The manufacturing method according to claim 11, wherein the concentration of the sol for fabricating the first electron transport layer is 50 mg/ml-150 mg/ml.

15. The manufacturing method according to claim 11, wherein a carrier mobility of the first electron transport layer is adjusted by an annealing temperature within a range of 120° C.-350° C.

16. The manufacturing method according to claim 15, wherein the first electron transport layer is formed by annealing at a temperature of 320° C. for 30 minutes.

17. The manufacturing method according to claim 12, wherein the concentration of the nanoparticle solution for fabricating the second electron transport layer is 10 mg/ml-50 mg/ml.

18. The manufacturing method according to claim 17, wherein the second electron transport layer with a thickness of 45 nm is formed by the nanoparticle solution of the concentration of 30 mg/ml.
